(19) United States
(12) Patent Application Publication
(10) Pub. No.: US 2010/0276731 A1
(43) Pub. Date: Nov. 4, 2010

(54) Inorganic Nanocrystal Bulk Heterojunctions

(75) Inventors: Chang-Yong Nam, Upton, NY (US); Charles T. Black, New York, NY (US)

Correspondence Address: BROOKHAVEN SCIENCE ASSOCIATES/;BROOKHAVEN NATIONAL LABORATORY, BLDG. 490C - P.O. BOX 5000, UPTON, NY, 11973, US

(73) Assignee: Brookhaven Science Associates, LLC., Upton, NY (US)

(21) Appl. No.: 12/772,256

(22) Filed: May 3, 2010

Related U.S. Application Data
(60) Provisional application No. 61/175,097, filed on May 4, 2009.

(51) Int. Cl. H01L 31/0264; H01L 29/12; H01L 21/04; H01L 31/18

(52) U.S. Cl. 257/184; 257/200; 438/478; 438/94; 977/773; 257/43; 257/E21.04; 257/E29.068; 257/E31.004

(57) ABSTRACT

A bulk heterojunction comprising an intermixed blend of fully inorganic n- and p-type particles and its method of manufacture are described. The particles are preferably nanometer-scale, spherical-shaped particles known as nanocrystals which are assembled into a densely packed three-dimensional array. The nanocrystals are preferably fabricated from a photo-active material which, in combination with the nanocrystal shape and size, can be engineered to produce a bulk heterojunction with a specific absorption spectrum. The bulk heterojunction is preferably formed by dispersing a predetermined ratio of the desired n- and p-type nanocrystals in an organic solvent and employing low-cost solution processing techniques to deposit a film having the desired thickness, relative concentration of nanocrystal types, and degree of intermixing onto a substrate. When incorporated as the active layer in optoelectronic devices such solar cells, fully inorganic bulk heterojunctions offer significant improvements in performance while maintaining the low costs associated with organic processing techniques.

The present invention was made with Government support under Contract No. DE-AC02-98CH10866 awarded by the U.S. Department of Energy. The United States Government has certain rights in the invention.

### BACKGROUND

I. Field of the Invention

This invention relates generally to thin film optoelectronic devices. In particular, the present invention relates to bulk heterojunctions fabricated with an active layer comprised entirely of inorganic nanocrystals. This invention further relates to the use of inorganic bulk heterojunctions in optoelectronic. devices such as photovoltaic cells.

II. Background of the Related Art

A photovoltaic cell is an energy conversion device capable of converting electromagnetic radiation into electrical energy. When the process involves the conversion of sunlight directly into electricity, this device is commonly referred to as a solar cell. The energy conversion process is based on the photovoltaic (PV) effect in which the absorption of incident photons on an active layer creates electron-hole pairs. Upon introduction of an internal or external electric field, the generated charge carriers migrate in opposite directions along a conducting path to create an electrical current. A number of materials in both bulk and thin film form have been used to fabricate PV cells with a power conversion efficiency (PCE) which depends on the type of material, its microstructure, and the overall construction of the PV cell. The science and technology of PV devices has received considerable attention, being the subject of numerous books, journal, and review articles including, for example, “Basic Research Needs for Solar Energy Utilization,” a report on the Basic Energy Sciences Workshop on Solar Energy Utilization held Apr. 18-21, 2005 which is incorporated by reference as if fully set forth in this specification.

From among the available materials used to fabricate PV cells, one of the most common is silicon (Si) which is typically used either as a bulk single crystal, as a polycrystalline material, or in thin film form. While the majority of silicon-based PV cells on the market today are fabricated from crystalline-Si technology, Si-based thin film PVs offer several advantages including more efficient utilization of source material, the capability for conformal coverage of the underlying substrate, and comparatively lower manufacturing costs. The PCE of microcrystalline and amorphous Si thin film PV cells has improved steadily, with the highest reported values being in the range of 10% to 20%. Despite the continued progression of Si thin film PVs, their material and manufacturing costs remain relatively high, making Si-based PV power production uncompetitive with conventional fossil fuel-based energy sources. Contributing factors include the need for large Si film thicknesses for efficient light absorption (≧200 μm), as well as their complex and expensive (requiring both time and energy) fabrication processes. This typically involves sequential deposition of a plurality of materials in one or more evacuated process chambers.

An attractive alternative to Si-based PV devices which has recently emerged involves the use of an organic layer as the active medium. Compared to Si-based PV devices, organic PV cells use lower-cost materials and simpler solution-based fabrication techniques. Generally, organic PV cells are formed with an organic film comprised of a photo-active polymer or some other small molecule which is layered between opposing planar electrodes. However, planar organic heterojunctions are generally inefficient as a photo-active layer since the diffusion length of generated bound electron-hole pairs (excitons) is much smaller than the optical absorption length. Improvements in device performance have been obtained by using an intermixed layer of electron-donating molecules (p-type material) and electron-accepting molecules (n-type material). The blended layer typically comprises a phase segregated mixture of donor and acceptor materials which is known as a bulk heterojunction. Experimental results have shown that bulk heterojunction PV devices have a higher conversion efficiency than planar devices due to the interpenetrating nature of the donor-acceptor interface. Examples of optoelectronic devices having a bulk heterojunction and their method of manufacture are provided by U.S. Pat. No. 7,435,617 to Shtein, et al. and U.S. Patent Application Publ. No. 2008/0012005 to Yang, et al., each of which is incorporated by reference in its entirety as if fully set forth in this specification.

Despite the potential of organic bulk heterojunction PVs, the highest PCE of these devices is only ˜3% to 5%, a value which, despite the lower manufacturing costs, is still too low for commercial applications. The low PCE is attributed primarily to (1) the intrinsically low carrier mobility of organic semiconductors and related material blends (typically several orders of magnitude lower than those of equivalent inorganic materials) and (2) the poor absorption band overlap between the organic semiconductor and the incident solar spectrum. Recent attempts to overcome these limitations have included replacing an organic semiconductor component with inorganic nanoparticles to create an active layer comprised of an organic-inorganic hybrid composite. An example is described in U.S. Patent Application Publ. No. 2005/0061363 to Ginley, et al., which is incorporated by reference in its entirety as if fully set forth in this specification. Another approach involves using an organic active layer component with a better absorption overlap with the solar spectrum. An example involves using a C₇₀ derivative as the n-type material in a polythiophene-C₆₀ based bulk heterojunction as disclosed by X. Wang, et al. in “Enhanced Photocurrent Spectral Response in Low-Bandgap Polyfluorene and C₇₀-Derivative-Based Solar Cell,” Advanced Functional Materials, 15, 1665 (2005), which is incorporated by reference in its entirety as if fully set forth in this specification.

Despite the improvements in organic PV devices achieved using these approaches, realization of commercially viable devices requires much more significant efficiency gains than what has been realized to date.

### SUMMARY

In view of the above-described problems, needs, and goals, one embodiment of the present invention provides an optoelectronic device fabricated with a bulk heterojunction as the photo-active layer which exhibits significant performance improvements while maintaining the low device fabrication costs associated with organic-based devices. In one embodiment this is accomplished by forming a bulk heterojunction from an intermixed blend of fully inorganic particles which are either n-type or p-type. The particles preferably have nanoscale dimensions along at least one of three orthogonal directions and are preferably spherical in shape.

In one embodiment, the inorganic bulk heterojunction is preferably formed from a plurality of p- and n-type nanocrystals of one or more semiconductor materials. Semiconductor materials used for the nanocrystals may include elemental semiconductors, compound semiconductors, and semiconducting alloys. The following conventions will be followed in this specification with regard to naming semiconducting materials. Group IV semiconductors include elemental semiconductors from Group IV of the periodic table of elements, e.g., diamond, semiconducting graphene, silicon, germanium, and semiconducting tin. Group IV semiconductors also include alloys consisting entirely of Group IV elements, such as Si₁₋ₓGeₓ, among others. Group III-V semiconductors are compounds or alloys comprising at least one element from Group III of the periodic table (Al, Ga., In) paired with at least one element from Group V of the periodic table (N, P, As, Sb) to form a line compound (GaN, InSb, etc.) or an alloy on either or both sublattices (In₁₋ₓGaₓAs, InAs_{1-y}P_{y}, In₁₋ₓGaₓAs_{1-y}P_{y}, etc.), where 0≦y≦1. Similarly, Group II-VI semiconductors comprise compounds of elements from Group II of the periodic table (Zn, Cd, Hg) and their alloys, and elements from Group VI (S, Se, Te) and their alloys. Group IV-VI semiconductors comprise elements from Group IV of the periodic table (Sn, Pb) and alloys thereof compounded with elements and alloys from Group VI, e.g., PbTe, Sn₁₋ₓ,PbₓTe, PbTe_{1-y}Se_{y}, etc. Metal oxide semiconductors include semiconducting compounds (stoichiometric and off-stoichiometric) of a metal with oxygen, such as ZnO, TiO₂, etc., where stoichiometry should not be assumed from the use of the stoichiometric formula in referring to the semiconductor. It is common practice for the subscripts indicating alloying to be omitted unless a precise value for the alloy composition is intended. Such practice will be followed hereinafter, i.e., In₁₋ₓGaₓAs will be referred to as InGaAs or GaInAs and PbTe_{1-y}Se_{y} will be referred to as PbTeSe or PbSeTe for ease of notation.

The nanocrystal components are mixed in a desired ratio which, in a preferred embodiment, is 1:1. The ratio of n-type to p-type nanocrystals used depends on a plurality of factors including, for example, the doping level, uniformity of mixing, as well as the nanocrystal shapes and sizes. The nanocrystals preferably have a diameter of 1 to 100 nm, but are not so limited and may be any shape or size. In a preferred embodiment the inorganic nanocrystals are dispersed in an organic solvent and formed into a thin film by solution processing. The thus-formed thin film comprises an intermixed layer of p- and n-type nanocrystals with a thickness which is preferably 100 nm to 1 μm. In another embodiment the organic solvent includes a surfactant to promote dispersion of the nanocrystals. The nanocrystals need not be completely, or even partially, dissolved in the solvent. Rather they may be dispersed to form a colloid or suspension, or they may form a true solution. All of these cases are referred to hereinafter as “solutions” for the purposes of describing the combination of nanocrystals dispersed in a solvent that may be further processed as if the combination were a true solution.

In still another embodiment, the bulk heterojunction is formed from p- and n-type nanocrystals whose concentration is graded across the thickness of the layer. Where the concentration of n-type nanocrystals increases in one direction, there is a concomitant increase in the concentration of p-type nanocrystals in the opposite direction. The grading may be linear or nonlinear and generally transitions from 100% n-type to 100% p-type across the thickness of the film. The transition between n-type and p-type may occur along either direction across the film thickness.

An additional embodiment relates to the formation of an optoelectronic device having an active layer comprised of an inorganic bulk heterojunction. The optoelectronic device is preferably a PV device, but may also be a light emitting diode, a photodetector, or a phototransistor. The optoelectronic device comprises at least a bottom electrode, an inorganic bulk heterojunction comprised of an intermixed layer of n- and p-type nanocrystals, and a top electrode. In a preferred embodiment the optoelectronic device comprises a blocking layer of n- or p-type nanocrystals of predetermined thickness which is present adjacent to and in contact with a surface of each opposing electrode.

Still another embodiment relates to a method of forming an inorganic bulk heterojunction. Individual intermixed layers are preferably formed using solution processing, but are not limited to this technique. Graded bulk heterojunctions are preferably formed by sequentially depositing a plurality of layers, each of which comprises a ratio of n-type to p-type nanocrystals which decreases with each successive layer. In this manner, the concentration of nanocrystals may be transitioned from 100% n-type to 100% p-type across the entire thickness of the blended layer. The transition may be linear, nonlinear, or step-wise, depending on the particular requirements.

### BRIEF DESCRIPTION OF THE DRAWINGS

FIG. 1 is a cross-sectional schematic of a bulk heterojunction photovoltaic device comprising an intermixed blend of inorganic p- and n-type nanocrystals as the active layer.

FIG. 2A shows the conduction and valence band offsets for a photovoltaic device formed with an active layer comprising a blend of p- and n-type Si nanocrystals.

FIG. 2B shows the conduction and valence band offsets for a photovoltaic device formed with an active layer comprising a mixture of p-type Si and n-type TiO₂ nanocrystals.

FIG. 3 is a cross-sectional illustration of a bulk heterojunction photovoltaic device comprised of single-component inorganic nanocrystal blocking layers which physically separate each electrode from the blended inorganic nanocrystal layer.

FIG. 4 shows a cross-section of a bulk heterojunction photovoltaic device with an active layer having a concentration of n- and p-type inorganic nanocrystals which is graded from one electrode to the other.

### DETAILED DESCRIPTION

In the interest of clarity, in describing the present invention, the following terms and acronyms are defined as provided below.

### Acronyms:

CVD: Chemical Vapor Deposition
ITO: Indium Tin Oxide
FTO: Fluorine Tin Oxide
PCE: Power Conversion Efficiency
PV: Photovoltaic
RIE: Reactive Ion Etching

### Definitions

Acceptor: A dopant atom which, when added to a semiconductor, can form p-type regions.
Donor: A dopant atom which, when added to a semiconductor, can form n-type regions.
Heterojunction: An interface or junction formed between dissimilar materials.
Inorganic: A material or compound which does not contain an organic compound.
Nanocrystal: Any manufactured structure or particle with nanometer-scale dimensions, i.e., 1 to 100 nm.
n-type: A semiconductor for which the predominant charge carriers responsible for electrical conduction are electrons. Normally, donor impurity atoms give rise to the excess electrons.
Optoelectronic: Of or relating to electronic devices which source, detect, and control electromagnetic radiation. This includes visible and invisible forms such as gamma rays, X-rays, ultraviolet, visible, and infrared radiation. Examples of optoelectronic devices include photovoltaic devices, photodetectors, phototransistors, and light emitting diodes.
Photovoltaics: The field of technology and research related to the conversion of electromagnetic radiation, e.g., sunlight, to electrical energy.
p-type: A semiconductor for which the predominant charge carriers responsible for electrical conduction are holes. Normally, acceptor impurity atoms give rise to the excess holes.

The present invention is based on the realization that the properties and performance of optoelectronic devices can be significantly improved by employing an active layer fabricated entirely from an intermixed blend of fully inorganic nanocrystals. By using inorganic nanocrystals, their superior light absorption efficiency, spectral absorption range, and carrier mobility can be exploited while maintaining the advantages of reduced cost and ease of manufacture associated with the fabrication techniques used for organic devices. Although this specification focuses primarily on applications involving PV devices, it is to be understood that the inorganic bulk heterojunctions which are disclosed and described may be employed in a wide variety of electronic or optoelectronic devices. This includes, but is not limited to, light emitting devices (LEDs), phototransistors, and photodetectors.

Conventional organic PV devices are comprised of three main components: (1) a transparent bottom electrical contact, (2) an organic layer as the photoactive material, and (3) a top metallic contact. The organic layer is typically formed from an organic solvent which is deposited onto an electrode using, for example, spin casting, dip coating, spray coating, ink jet printing, or any other technique which is well-known to those skilled in the art. The organic layer serves as the photo-active material which absorbs electromagnetic radiation, e.g., sunlight, and generates electron-hole pairs or excitons over a wavelength range corresponding to the band gap of the organic layer. The present invention replaces the organic layer in an organic PV device with a layer of intermixed and densely packed p- and n-type inorganic particles with a thickness on the order of a few hundred nanometers.

### I. Nanocrystal Synthesis

Nanometer-scale particles, which are also known as nanoparticles, nanocrystals, or quantum dots, have been formed from a wide variety of materials using a number of different techniques which involve both top-down and bottom-up approaches. Examples of the former include standard photolithography techniques, dip-pen nanolithography, and focused ion-beam etching. The latter comprises techniques such as electrodeposition or electroplating onto templated substrates, laser ablation of a suitable target, vapor-liquid-solid growth of nanowires, and growth of surface nanostructures by thermal evaporation, sputtering, chemical vapor deposition (CVD), or molecular beam epitaxy (MBE) from suitable gas precursors and/or solid sources.

Nanoparticles may also be formed using conventional powder-processing techniques such as comminution, grinding, or chemical reactions. Examples of these processes include mechanical grinding in a ball mill, atomization of molten metal forced through an orifice at high velocity, centrifugal disintegration, sol-gel processing, or vaporization of a liquefied metal followed by supercooling in an inert gas stream. Nanoparticles synthesized by chemical routes may involve solution-phase growth in which, as an example, sodium boronhydride, superhydride, hydrazine, or citrates may be used to reduce an aqueous or nonaqueous solution comprising metal salts. Powder-processing techniques are advantageous in that they are generally capable of producing large quantities of nanometer-scale particles with desired size distributions.

The inorganic particles are preferably spherical or spheroidal with a size ranging from 1 to 100 nm along at least one of three orthogonal dimensions. It is to be understood, however, that the particles may take on any shape, size, and structure as is well-known in the art. This includes, but is not limited to branching, conical, pyramidal, cubical, cylindrical, mesh, fiber, cuboctahedral, and tubular nanoparticles. It is further understood that the size is not limited to the nanometer range and may extend into the micrometer and millimeter range. The nanoparticles may be agglomerated or dispersed, formed into ordered arrays, fabricated into an interconnected mesh structure, either formed on a supporting medium or suspended in a solution, and may have even or uneven size distributions. The particle shape and size is preferably configured to facilitate intermixing and efficient dispersal on the underlying substrate with close packing in three dimensions. The particles themselves are preferably crystalline to facilitate carrier transport and are thus referred to as nanocrystals. Throughout this specification, the particles will be primarily disclosed and described as nanocrystals which are essentially spherical in shape.

The nanocrystals are preferably inorganic nanoparticles which are soluble or dispersible in an organic solvent. The individual nanocrystals may be surrounded by a monolayer or more of a passivating material which may be, for example, a halide from group VII of the periodic table. Such a passivating layer imparts improved stability, increased solubility, and provides control over the electronic properties of the surface. The shape, size, and composition of the nanocrystals may be tailored to obtain the desired band gap, as well as to maximize the absorption of electromagnetic radiation and formation of electron-hole pairs. In a preferred embodiment the band gap is from about 1 to 2.5 eV corresponding to a wavelength range of about 500 to 1240 nm, which shows excellent overlap with the solar spectrum. The nanocrystals preferably have dimensions ranging from 1 to 100 nm, but are not so limited. In an even more preferred embodiment the nanocrystals have dimensions of 1 to 20 nm. The band gap of a nanocrystal has been observed to be proportional to its size with an increase in band gap observed for a corresponding decrease in particle size.

In one embodiment the nanocrystals are formed from a semiconducting material such as the group IV, III-V, II-VI, or IV-VI semiconductors which include, for example, silicon (Si), germanium (Ge), carbon (diamond or semiconducting graphene) (C), tin (Sn), lead (Pb), gallium arsenide (GaAs), indium phosphide (InP), indium nitride (InN), indium arsenide (InAs), cadmium selenide (CdSe), cadmium sulfide (CdS), lead sulfide (PbS), lead telluride (PbTe), zinc sulfide (ZnS), or cadmium telluride (CdTe). The semiconductor used may also be an alloy of one or more semiconductors such as SiGe, GaInAs, or CdInSe and is generally suitably doped to form separate n-type (donor) or p-type (acceptor) nanocrystals. Chemical routes for making doped and undoped group-IV semiconductor nanocrystals have been described, for example, in U.S. Pat. Nos. 6,855,204 and 7,267,721, both of which are to Kauzlarich, et al. and, along with the references cited therein, are incorporated by reference in their entireties as if fully set forth in this specification.

In another embodiment, nanocrystals formed from inorganic metal oxide particles such as, for example, Cu₂O, TiO₂, or ZnO, which exhibit suitable light-absorption and photo-active properties are used. An example is provided by U.S. Pat. No. 6,849,798 to Mitra, et al. which discloses the inclusion of a nanocrystalline layer of Cu₂O in an organic solar cell. Another example is U.S. Patent Application Publ. No. 2006/0032530 to Afzali-Ardakani, et al. which discloses an organic semiconductor device comprising soluble semiconducting inorganic nanocrystals interspersed within an organic layer of pentacene. Each of the aforementioned is incorporated by reference in its entirety as if fully set forth in this specification.

### II. Synthesis of an Inorganic Bulk Heterojunction

Utilization of the nanocrystals in an optoelectronic device requires that nanocrystals with the desired composition, shape, and size be deposited in the form of a thin film. This is accomplished by initially mixing the appropriate ratio of n- and p-type nanocrystals in an organic solvent. The nanocrystal concentration and ratio may be adjusted to obtain the desired degree of intermixing between constituent nanocrystal types. It is to be understood that the organic solvent is merely used as a dispersing medium and is not itself an active layer which contributes to the generation and transport of charge carriers. Any common organic solvent which is well-known in the art and is capable of dissolving or dispersing the desired nanocrystals may be used. Some typical examples include ethanol, methanol, isopropyl alcohol, chloroform, chlorobenzene, hexane, and xylene. A specific example includes the use of octane or toluene for PbS nanocrystals with the former being disclosed, for example, by D. Barkhouse, et al. in “Thiols Passivate Recombination Centers in Colloidal Quantum Dots Leading to Enhanced Photovoltaic Device Efficiency,” ACS Nano, 2, 2356 (2008) which is incorporated by reference in its entirety as if fully set forth in this specification. Depending on the nature of the nanocrystal and its surface structure, a surfactant may be used in combination with the organic solvent to promote uniform dispersion of the nanocrystals. Typical surfactants include, for example, alkane thiol, oleic acid, tetra ammonium bromide, and pentaethylene glycol monododecyl ether, some of which are disclosed by E. Klem, et al. in “Efficient Solution-processed Infrared Photovoltaic Cells: Planarized All-Inorganic Bulk Heterojunction Devices Via Inter-Quantum-Dot Bridging During Growth From Solution,” Appl. Phys. Lett. 90, 183113 (2007) and by R. Tilley, et al. in “The Microemulsion Synthesis of Hydrophobic and Hydrophilic Silicon Nanocrystals,” Advanced Materials 18, 2053 (2006), each of which is incorporated by reference in its entirety as if fully set forth in this specification. The nanocrystals are thoroughly mixed in the solvent with no significant agglomeration, forming a mixed blend of the constituent nanocrystals. If necessary, dispersion may be further improved by ultrasonication.

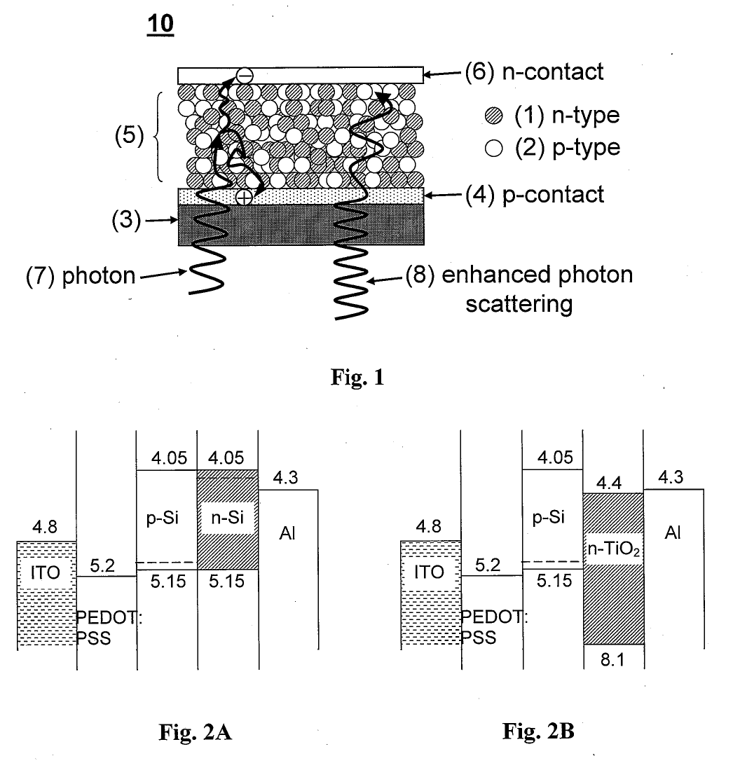

The nanocrystal-containing organic solvent may then be formed into active layer of fully inorganic nanocrystals by solution processing. The basic process involves applying the solvent to a substrate and using spin-coating to form a nanocrystal film with the desired thickness. It is to be understood, however, that the deposition process is not limited to spin-coating, but may also use other technique as is well-known in the art. This includes, for example, dip coating, spray coating, or ink jet printing. The thickness is preferably 100 to 1 μm, but is not so limited and may be controlled through changes in the viscosity of the solvent as well as the spinning speed and duration. In an especially preferred embodiment the film thickness is in the range of 100 to 200 nm. The thus-formed thin film is characterized as a bulk heterojunction comprised of an interpenetrating network of acceptor and donor nanocrystals. An example of such a structure is provided in FIG. 1 which will be described in further detail below. In FIG. 1, a cross-section of a layer comprising individual inorganic n-type (1) and p-type (2) nanocrystals is shown as a close-packed blend of spherical particles (5).

Once a fully inorganic bulk heterojunction is formed as described above, additional processing steps may be performed to, for example, remove the organic solvent and promote electrical contact between individual nanocrystals. This may involve thermal annealing, UV/ozone cleaning, ion beam etching, plasma treatments, or additional chemical processing. This is especially desirable when a surfactant is used in solution since it is necessary to remove any non-conducting surface layer which may prevent formation of good electrical contact between neighboring nanocrystals or with the electrodes.

### A. Optoelectronic Devices

An embodiment describing a method of forming an electronic or optoelectronic device having a bulk heterojunction comprised entirely of inorganic nanocrystals will now be described in detail with reference to FIG. 1. It is to be understood that this embodiment is merely exemplary and is used to describe a mode of practicing the invention. There are many possible variations which do not deviate from the spirit and scope of the present invention and these variations may serve as functional equivalents. FIG. 1 shows a cross-sectional schematic of a typical PV device (10) comprising a bottom electrode (4), a photo-active nanocrystal blend layer (5), and a top electrode (6).

Initially the bottom electrode (4) is formed on a suitable substrate (3) which may be any insulating material as is well-known in the art such as a glass, ceramic, plastic, or any other related material. If light is to be incident from the bottom as is illustrated by the direction of the incident photon (7) in FIG. 1, it is preferable that both the substrate (3) and bottom electrode (4) be transparent. It is to be understood, however, that the degree of transparency may vary and that the substrate (3) and bottom electrode (4) may be translucent. The bottom electrode (4) is an electrical conductor, preferably a transparent material such as indium tin oxide (ITO) or fluorine tin oxide (FTO) which may be formed using any of a wide variety of thin film deposition processes which are well-known in the art. These include, but are not limited to, thermal evaporation, CVD, sputtering, or electrodeposition. Alternatively, the bottom electrode may be formed through solution processing of metallic nanocrystals. Although in this embodiment the bottom electrode (4) is transparent, it is to be understood that either or both of the top (6) and bottom (4) contacts may be fabricated from a transparent electrical conductor.

Deposition of the bottom electrode (4) is followed by formation of a bulk heterojunction (5) from an intermixed blend of n- (1) and p-type (2) inorganic nanocrystals having the desired shape and ratio, e.g., a 1:1 volume mixture, as described in Section I above. It is to be understood that corresponding p- and n-type nanocrystals used within the same bulk heterojunction may have different shapes and sizes. A simple 1:1 ratio is ideal in the simple case where the sizes of p- and n-type nanocrystals are identical and they are fully intermixed. However, if different sized p- and n-type nanocrystals are mixed, the optimal ratio would differ from 1:1. The need to use different sized particles may stem from (1) limitations arising due to particle size control, (2) the need to optimize the overlap of optical absorption, i.e., energy band gap, of the particles with the solar spectrum and, more importantly, (3) a need to control the energy level alignment that allows efficient free charge carrier separation at the junctions. Due to quantum confinement effects, it is highly likely that absorbed photons create excitons (bound electron-hole pairs) rather than free charge carriers. Proper energy level alignment would be even more important for the dissociation of excitons into free carriers. The particle size below which quantum confinement effects become significant depends on the material system used. Consequently there will be situations where it is necessary to use p- and n-type particles of different sizes.

Depending on the type of organic solvent used, whether a surfactant is included, and whether a passivating surface layer is present, it may be necessary to perform further processing after deposition of the nanocrystal film. As an example, the organic solvent may be decomposed/desorbed by thermal annealing, reactive ion etching (RIE), plasma treatment, ion beam etching, or by chemical means. This treatment process may be optimized to promote electrical contact between individual nanocrystals as well as between the nanocrystals and the metallic contacts (4) and (6) without affecting the optoelectronic properties of the overall structure. After formation of an intermixed inorganic nanocrystal layer (5) with the desired thickness and composition, the top metallic contact (6) is deposited onto the active layer (5). This is preferably accomplished using physical vapor deposition techniques such as thermal evaporation or sputtering, although other film growth techniques which are well-known in the art may be used. In another embodiment, one or both of the top and bottom electrodes may be fabricated by solution processing using metallic nanocrystals.

Proper operation of the thus-formed bulk heterojunction PV device (10) requires careful selection of the materials used as the donor (1) and acceptor (2) components of the nanocrystal blend active layer (5) as well as the top (6) and bottom (4) electrodes. The operation and overall performance of the thus-formed PV device (10) can be further tuned and optimized by varying parameters including the nanocrystal size and shape, the blended layer thickness, and the ratio of acceptor and donor nanocrystals. For efficient transfer of charge carriers from the nanocrystals to a metal electrode, the work function of the metal should be properly aligned with the energy levels of the nanocrystals. For example, to collect electrons from n-type nanocrystals the work function of the metal contact should be close to the lowest unoccupied molecular orbital (LUMO) level, i.e., the conduction band edge for a bulk semiconductor, which is itself determined by, i.e., is specific to, the material used. Similar to organic bulk heterojunction PV devices, each contact (4) and (6) is designed to be selective to one type of charge carrier and must be specific to the materials used in the nanocrystal blend.

For the nanocrystal blend active layer, the n- and p-type components are chosen based on a consideration of the relative conduction and valence band offsets. Examples are provided in FIGS. 2A and 2B which show the band offset for PV devices comprised of an ITO bottom electrode, an intermediate layer of PEDOT:PSS, an active layer comprised of a blend of nanocrystals of p-type Si with either n-type Si or n-type TiO₂, and an aluminum (Al) top electrode. The intermediate layer of PEDOT:PSS shown in FIGS. 2A and 2B is incorporated since its work function is a good match to that of the nanocrystals. For good carrier collection efficiency, use of a material whose work function matches that of the semiconductor used is desirable. In many cases, a metal with a work function which is a suitable match to the employed semiconductor's is not available. This issue may be solved by incorporating a thin intermediate layer with decent conductivity/mobility (albeit not as good as a metal) which is a better work function match. In FIGS. 2A and 2B, a thin layer of PEDOT:PSS is used although other materials such as V₂O₅ or NiO have been found to be suitable.

In FIG. 2A, the active layer is comprised of a bulk heterojunction of n- and p-type Si nanocrystals whereas FIG. 2B shows an active layer of p-type Si and n-type TiO₂. Although it is to be understood that the valence and conduction band energies vary in proportion to the size of the nanocrystals, values for bulk Si and TiO₂ are used for illustrative purposes and the sake of clarity. FIGS. 2A and 2B show valence and conduction band energies of Si as 5.15 and 4.05 eV, respectively. The band offset shown in FIG. 2A produces an internal electric field which provides a potential difference which, upon generation of an electron-hole pair by a photon (7) incident upon the p-Si and n-Si interface, is sufficient to drive electrons through the n-type Si nanocrystals to the Al electrode and holes through the p-type Si nanocrystals toward the ITO electrode, thereby supplying an electrical current. The band offset arising from the combination of materials used in FIG. 2B yields a similar effect. Strictly speaking, the p-Si/n-Si nanocrystal mixture in FIG. 2A is a bulk homojunction rather than a heterojunction since the same material (Si) is used throughout. On the other hand, the p-Si/n-TiO₂ nanocrystal mixture illustrated in FIG. 2B can be considered a true bulk heterojunction since dissimilar materials are used. Therefore it is to be understood that although the term bulk heterojunction is used throughout this specification, it also encompasses nanocrystal mixtures of the same material which has been suitably doped to yield p- and n-type nanocrystals.

A PV device fabricated with an active layer comprised entirely of inorganic nanocrystals offers several advantages over devices with an organic component. In general, inorganic nanocrystals have much higher absorption efficiency and carrier mobility than organic photoactive materials. Since the carrier diffusion length is higher, there is a greater probability that generated charge carriers will be able to migrate to their respective electrodes before recombination occurs. The use of inorganic nanocrystals permits the absorption spectrum to be tailored via changes in the nanocrystal materials as well as their shapes and sizes. Since the PV device can be conveniently engineered to efficiently absorb a larger portion of the solar spectrum (or any other desired wavelength range), higher power conversion efficiencies may be attained. The absorption probability is further enhanced by the interpenetrating nature of the interface between p- and n-type materials as is present in a bulk heterojunction. Since the interface extends through the bulk it covers a surface area larger than that attainable with a planar device. The random arrangement of nanocrystals within the active layer promotes internal scattering of incident photons, thereby increasing the probability of absorption and generation of an electron-hole pair. Furthermore, since the blended inorganic nanocrystal layer can be formed using solution processing techniques, an optoelectronic device can be fabricated that combines the higher power conversion efficiency of an inorganic photoactive layer with the low-cost processing techniques commonly used for organic materials.

### B. Blocking Layers

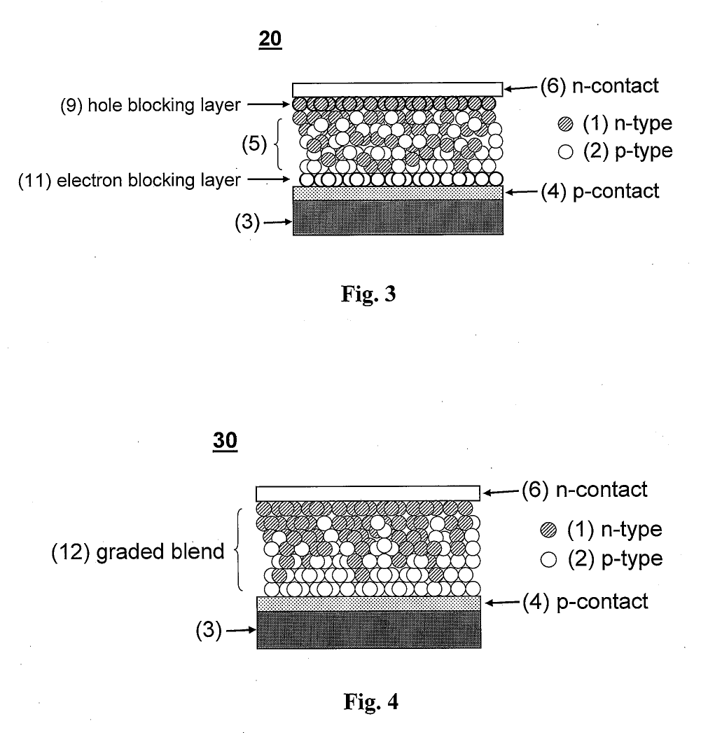

The random, interpenetrating nature of the blended active layer means there exists the possibility that a percolating path through nanocrystals of the same type may form across the thickness of the blended layer. That is, a path for current to flow along solely n-type or p-type nanocrystals from one electrode to the other may exist. This has the effect of creating a shorting path through the device. In one embodiment, this deleterious effect may be minimized through selection of top and bottom electrodes with the appropriate work function as discussed in Section A above and with reference to FIGS. 2A and 2B. However, even with proper design of band offsets, significant leakage currents may still exist. One solution involves the use of blocking layers of a single nanocrystal component at opposing electrodes to prevent short-circuiting. An example is shown by the bulk heterojunction PV device (20) illustrated in FIG. 3.

In this embodiment a hole blocking layer (9) is formed adjacent to the top electrode (6) which serves as the n-type contact whereas an electron blocking layer (11) is formed on the bottom electrode (4) which is the p-type contact. The hole blocking layer (9) is comprised entirely of n-type nanocrystals (1) whereas the electron blocking layer (11) is comprised entirely of p-type nanocrystals (2). Since the bottom electrode (4) is fully coated with p-type nanocrystals (2), n-type nanocrystals (1) from the intermixed blend layer (5) are prevented from coming into contact with the bottom electrode (4) and creating a short circuit. Similarly, the top electrode (6) is fully covered with n-type nanocrystals (1), preventing p-type nanocrystals (2) from coming into contact with the top electrode (6). Although FIG. 3 shows that only a single layer of nanocrystals is used as a blocking layer it is to be understood that thicker blocking layers may be formed. Furthermore, it is to be understood that the n- or p-type blocking layers can be positioned at either the top or bottom electrode.

An optoelectronic device comprising electron and hole blocking layers may be fabricated using methods analogous to those used to form the bulk heterojunction (5). However, instead of dispersing a mixture of n-type and p-type nanocrystals in a solvent, only a single type of nanocrystal is included. For example, an organic solvent carrying exclusively p-type nanocrystals is initially dispersed on the bottom electrode (4). This results in the formation of a film comprised entirely of p-type nanocrystals (11). This is followed by the formation of a bulk heterojunction (5) comprising both n- and p-type nanocrystals as described in Section A above. The hole blocking layer (9) is then formed on top of the bulk heterojunction from a solution comprised entirely of n-type nanocrystals. Finally, the top electrode is deposited onto the hole blocking layer (9) to form the PV device (20) shown in FIG. 3.

### C. Graded Bulk Heterojunction

The random nature of the nanocrystal blend layer may also result in individual nanocrystals or clusters of nanocrystals which are isolated within the bulk of the blended layer and therefore prevented from contributing to current generation. For example, a single n-type nanocrystal or cluster of n-type nanocrystals may end up being surrounded entirely by p-type nanocrystals. In this case charge carriers generated within the isolated n-type region are prevented from migrating to the n-type electrode. The occurrence of this condition may be minimized by forming a graded bulk heterojunction. In this embodiment, the concentration of each component in the nanocrystal blend layer is inversely graded across the thickness of the bulk heterojunction.

An example of such a structure is illustrated by the PV device (30) in FIG. 4. The concentration of n-type nanocrystals (1) is gradually decreased from 100% at the surface of the top electrode (6) to zero at the bottom electrode (4) whereas the concentration of p-type nanocrystals (2) is the inverse, increasing from zero at the top electrode (6) to 100% at the bottom electrode (4). This produces a graded blend inorganic bulk heterojunction (12) illustrated in FIG. 4. A graded blend active layer (12) minimizes the formation of isolated regions of one component and facilitates more efficient transport of photo-generated charge carriers towards the appropriate electrode. It is to be understood that the grading rate and overall thickness of the graded blend active layer (12) may be varied to suit the needs of a particular application. This includes the use of either linear, nonlinear, or stepped grading schemes as well as various combinations of these through the thickness of the active layer.

One method of fabricating graded bulk heterojunctions of the type shown in FIG. 4 involves forming a sequence of layers from differing single-component or blended n- and p-type nanocrystal solutions. For example, an initial solution of 100% n-type nanocrystals is coated onto the bottom electrode (4). This is followed by a second coating using a nanocrystal solution having 90% n-type and 10% p-type nanocrystals. The coating process is repeated using solutions with increasing p-type fraction until a final layer comprised entirely of p-type nanocrystals is coated at the top of the thus-formed structure. The thickness of individual layers as well as the overall grading rate may be arbitrarily chosen depending on the requirements for a particular application or device.

III. Exemplary Embodiment

An exemplary embodiment of the present invention will now be described in detail. In this embodiment, fabrication of a PV device comprising a fully inorganic bulk heterojunction as the photo-active layer will be explained with reference to FIG. 1. The substrate (3) comprises a clean glass plate onto which a 100- to 200-nm-thick layer of ITO is deposited by sputter deposition to form the bottom electrode (4). ITO is chosen as the bottom electrode due to its high electrical conductivity and transparency. The ITO may be patterned into electrical contacts using standard photolithography or any other patterning technique as is well-known in the art.

Nanocrystals of Si are prepared by ball milling a porous Si wafer etched by electrochemical means to form substantially spherical particles with a diameter of nominally 5 to 10 nm. The carrier type of the thus-formed Si nanocrystals follows the doping type and level of the native Si wafer used in their manufacture. P-type nanocrystals are generally formed by doping with boron (B) whereas n-type nanocrystals are often formed by phosphorous (P) doping. A 1:1 mixture of the two nanocrystal components is mixed with a solvent of xylene to form a solution having a 1.0% (w/w) concentration of nanocrystals. The desired quantity of the thus-formed solution is subject to ultrasonication for 60 minutes to promote uniform dispersion and intermixing of the constituent nanocrystal types. The solution is then applied to the ITO-patterned glass substrate and spun on at a speed of nominally 1000 rpm to form a 100- to 200-nm-thick bulk heterojunction (5). This is followed by annealing at 500° C. under a nitrogen-argon-hydrogen ambient to vaporize the solvent, remove any native Si oxide layer capping the nanocrystal surfaces, and promote uniform and dense packing of the nanocrystals. Subsequent exposure to an argon plasma at a power of 50 Watts is performed to promote electrical contact between individual nanocrystals as well as with the subsequent top electrode. The nanocrystal layer may also be patterned and etched to constrain the thus-formed film to regions having a bottom electrode.

A top electrode (6) comprised of a 100-nm-thick film of Al is subsequently deposited on the fully inorganic bulk heterojunction by DC sputtering. The Al layer may also be suitably patterned and etched to form individual electrodes as well as the appropriate electrical wiring. During operation of the PV device (10), electromagnetic radiation (7) is incident on the glass substrate (3) on a side opposite the transparent ITO bottom electrode (4). The photon may be scattered (8) and is subsequently absorbed at an interface between p-type (2) and n-type (1) nanocrystals within the bulk heterojunction (5). This creates an electron-hole pair and, due to the band offset induced by the ITO and Al electrodes, causes electrons to flow through the n-type nanocrystals (1) towards the top Al electrode (6) and holes to flow through the p-type nanocrystals (2) toward the bottom ITO electrode (3). This creates an electrical current which flows through the electrical circuit created by wiring connected to the top (6) and bottom (4) electrodes.

It will be appreciated by persons skilled in the art that the present invention is not limited to what has been particularly shown and described in this specification. Rather, the scope of the present invention is defined by the claims which follow. It should further be understood that the above description is only representative of illustrative examples of embodiments. For the reader's convenience, the above description has focused on a representative sample of possible embodiments, a sample that teaches the principles of the present invention. Other embodiments may result from a different combination of portions of different embodiments.

The description has not attempted to exhaustively enumerate all possible variations. That alternate embodiments may not have been presented for a specific portion of the invention, and may result from a different combination of described portions, or that other undescribed alternate embodiments may be available for a portion, is not to be considered a disclaimer of those alternate embodiments. It will be appreciated that many of those undescribed embodiments are within the literal scope of the following claims, and others are equivalent.

1. A bulk heterojunction comprising:
a plurality of n-type inorganic nanocrystals; and
a plurality of p-type inorganic nanocrystals,
wherein a predetermined ratio of said n-type inorganic nanocrystals to said p-type inorganic nanocrystals is in the form of an intermixed and densely packed film.

2. The bulk heterojunction of claim 1 wherein one of the plurality of n-type inorganic nanocrystals or the plurality of p-type inorganic nanocrystals is formed from a semiconductor selected from at least one of the Group IV semiconductors, Group III-V semiconductors, Group II-VI semiconductors, and Group IV-VI semiconductors.

3. The bulk heterojunction of claim 1 wherein one of the plurality of n-type inorganic nanocrystals or the plurality of p-type inorganic nanocrystals is formed from a semiconducting metal oxide.

4. The bulk heterojunction of claim 1 wherein the predetermined ratio of said n-type inorganic nanocrystals to said p-type inorganic nanocrystals is 1:1.

5. The bulk heterojunction of claim 1 wherein the nanocrystals have dimensions of 1 to 100 nm along at least one of three orthogonal directions, and the film has a thickness of 100 nm to 1 μm.

6. The bulk heterojunction of claim 5 wherein the nanocrystals have dimensions of 1 to 20 nm along at least one of three orthogonal directions, and the film has a thickness of 100 to 200 nm.

7. The bulk heterojunction of claim 1 wherein the predetermined ratio of said n-type inorganic nanocrystals to said p-type inorganic nanocrystals is graded along the film thickness.

8. The bulk heterojunction of claim 7 wherein the grading is nonlinear.

9. An optoelectronic device comprising:
a bottom electrode;
a bulk heterojunction comprising:
a plurality of n-type inorganic nanocrystals; and
a plurality of p-type inorganic nanocrystals,
wherein a predetermined ratio of said n-type inorganic nanocrystals to said p-type inorganic nanocrystals is in the form of an intermixed and densely packed film; and
a top electrode.

10. The optoelectronic device of claim 9 further comprising a blocking layer of n-type nanocrystals with a first predetermined thickness located at a first planar surface of the bulk heterojunction and a blocking layer of p-type nanocrystals with a second predetermined thickness located at a second planar surface of the bulk heterojunction, the second planar surface located opposite to the first planar surface.

11. The optoelectronic device of claim 9 wherein the predetermined ratio of said n-type inorganic nanocrystals to said p-type inorganic nanocrystals is graded along the film thickness.

12. The optoelectronic device of claim 11 wherein the grading is nonlinear.

13. The optoelectronic device of claim 9 wherein at least one of the top electrode and the bottom electrode comprises indium tin oxide.

14. A method of forming an inorganic bulk heterojunction, the method comprising:
forming a plurality of inorganic n-type and p-type nanocrystals;
dispersing said n-type and p-type inorganic nanocrystals in a solvent; and
depositing a film of said inorganic nanocrystals on a substrate.

15. The method of claim 14 wherein the film is formed by solution processing.

16. The method of claim 14 wherein the solvent is an organic solvent.

17. The method of claim 14 wherein the solvent comprises a surfactant.

18. A method of forming a graded bulk heterojunction, the method comprising:
depositing a first layer consisting of inorganic n-type nanocrystals;
sequentially depositing a plurality of layers, each of which layers comprises a ratio of n-type to p-type nanocrystals which decreases with each successive layer; and
depositing a final layer consisting of inorganic p-type nanocrystals.

19. A method of forming an optoelectronic device with an inorganic bulk heterojunction, the method comprising:
depositing a bottom electrode on a substrate;
forming an inorganic bulk heterojunction by dispersing a plurality of n-type and p-type inorganic nanocrystals in a solvent and depositing a film of said inorganic nanocrystals on the bottom electrode; and
depositing a top electrode.

20. A method of forming an optoelectronic device with a graded inorganic bulk heterojunction, the method comprising:
depositing a bottom electrode on a substrate;
forming on the bottom electrode a graded inorganic bulk heterojunction by depositing a first layer consisting of inorganic nanocrystals of a first doping type, sequentially depositing a plurality of layers, each of which comprises a ratio of nanocrystals of the first doping type to nanocrystals of a complementary doping type, which ratio decreases with each successive layer;
and depositing a final layer consisting of the nanocrystals of the complementary doping type; and
depositing a top electrode.
